(19) United States
(12) Patent Application Publication
(10) Pub. No.: US 2010/0065803 A1
(43) Pub. Date: Mar. 18, 2010

(54) MEMORY DEVICE AND MANUFACTURING METHOD THEREOF

(75) Inventors: Sung-Yool Choi, Daejon (KR); Min-Ki Ryu, Seoul (KR); Hu-Young Jeong, Daejon (KR)

Correspondence Address: AMPACC Law Group, 3500 188th Street S.W., Suite 103, Lynnwood, WA, 98037, US

(73) Assignee: Electronics and Telecommunications Research Institute, Daejon (KR)

(21) Appl. No.: 12/517,554

(22) PCT Filed: Nov. 28, 2007
(86) PCT No.: PCT/KR2007/006062

§ 371 Date: Jun. 3, 2009

(30) Foreign Application Priority Data
Dec. 4, 2006 (KR) 10-2006-0121755
Aug. 23, 2007 (KR) 10-2007-0084717

(51) Int. Cl. H01L 45/00; H01L 21/28

(52) U.S. Cl. 257/4; 438/680; 257/E45.002; 257/E21.158

(57) ABSTRACT

Provided is a resistance variable non-volatile memory device using a trap-controlled Space Charge Limited Current (SCLC), and a manufacturing method thereof. The memory device includes a bottom electrode; an inter-electrode dielectric thin film diffusion prevention film formed on the bottom electrode; a dielectric thin film formed on the inter-electrode dielectric thin film diffusion prevention film and having a plurality of layers with different charge trap densities; and a top electrode formed on the dielectric thin film.

### TECHNICAL FIELD

The present invention relates to a memory device and a manufacturing method thereof; and more particularly, to a resistance variable non-volatile memory device using a trap-controlled Space Charge Limited Current (SCLC), and a manufacturing method thereof.

### BACKGROUND ART

As various types of electronic products, such as portable computers, mobile phones, MP3 players, and digital cameras, gradually get smaller and multifunctional, there is growing demand for low power and high integration of a non-volatile memory device that is an information storage device used for these devices.

Currently, flash memories based on the control of electrons in a floating gate are taking the lead in the non-volatile memory technology. However, since such a flash memory has a structure in which electrons are controlled by applying a high electric field to a floating gate, the device structure becomes relatively complicated as compared to those of other memory devices, thus making it difficult to achieve high integration.

To overcome this problem, the Ovonic Unified Memory (OUM) using a phase change material has been proposed. The OUM is also called a Phase-change Random Access Memory (PRAM), and uses a difference in electrical conductivity between a crystalline state and a non-crystalline state of a phase change material layer. This phase change memory device has a simple structure compared to a flash memory, so that it can be highly integrated in theory.

However, heat is required for a phase change from the crystalline state to the non-crystalline state of the phase change material layer or vice versa in the OUM, which requires a current of about 1 mA per cell. Consequently, thick wirings are needed in order to supply sufficient current. This again makes it difficult to obtain high integration.

As a memory device of another type, a Resistive Random Access Memory (ReRAM) has been much studied in recent years, which is a non-volatile memory device using a material allowing an electrical resistance to vary without a phase change. However, the ReRAM has the drawback that a high electric driving force is required due to a large amount of current consumed upon operating the device because it shows a metal current characteristic in a low resistance state. Further, it is not easy to manufacture the ReRAM because the reproducibility of the device is low.

### DISCLOSURE OF INVENTION

### Technical Problem

It is, therefore, an object of the present invention to provide a resistance variable non-volatile memory device using a trap-controlled SCLC, and a manufacturing method thereof.

Another object of the present invention is to provide a memory device which can effectively control the charge trap distribution of a resistance variable non-volatile memory device using a trap-controlled SCLC, and a manufacturing method thereof.

Still another object of the present invention is to provide a memory device which can be highly integrated by a simple manufacturing process, and a manufacturing method thereof.

Other objects and advantages of the present invention can be understood by the following description, and become apparent with reference to the embodiments of the present invention. Also, it is obvious to those skilled in the art of the present invention that the objects and advantages of the present invention can be realized by the means as claimed and combinations thereof.

### Technical Solution

In accordance with an aspect of the present invention, there is provided a memory device, which includes: a bottom electrode; an inter-electrode dielectric thin film diffusion prevention film formed on the bottom electrode; a dielectric thin film formed on the inter-electrode dielectric thin film diffusion prevention film and having a plurality of layers with different charge trap densities; and a top electrode formed on the dielectric thin film.

The plurality of layers in the dielectric thin film may be formed of the same dielectric material or a different dielectric material, and a different Space Charge Limit Current (SCLC) may flow in the dielectric thin film depending on the charge trap densities.

The dielectric thin film may be formed of one of dielectric metal oxides comprised of a combination of one metal selected from the group consisting of titanium (Ti), vanadium (V), chrome (Cr), manganese (Mn), iron (Fe), cobalt (Co), nickel (Ni), copper (Cu), zinc (Zn), yttrium (Y), zirconium (Zr), niobium (Nb), lead (Pb), hafnium (Hf), tantalum (Ta), tungsten (W), and palladium (Pb) and oxide. The dielectric thin film may be formed of a material in which one element selected from the group consisting of titanium (Ti), vanadium (V), chrome (Cr), manganese (Mn), iron (Fe), cobalt (Co), nickel (Ni), copper (Cu), zinc (Zn), zirconium (Zr), hafnium (Hf), niobium (Nb), tantalum (Ta), lead (Pb), and lanthane (La) group elements is added to the aforementioned dielectric metal oxides, as an impurity.

The dielectric thin film may be formed to have a thickness of 3 nm to 100 nm, the materials forming the dielectric thin film have a dielectric constant of 3 to 1,000

The inter-electrode dielectric thin film diffusion prevention film may be formed of one selected from the group consisting of Al₂O₃, SiO₂, ZnO₂, MN and Si₃N₄.

The inter-electrode dielectric thin film diffusion prevention film and the internal diffusion prevention film may be formed of an organic self-assembled monolayer. The inter-electrode dielectric thin film diffusion prevention film and the internal diffusion prevention film are formed to have a thickness of 05 nm to 3 nm.

The top electrode and the bottom electrode are formed of one conductive oxide selected from the group consisting of ITO, IZO, RuO₂, and IrO₂.

In accordance with an aspect of the present invention, there is provided a manufacturing method of a memory device, which includes the steps of: a) forming a bottom electrode; b) forming an inter-electrode dielectric thin film diffusion prevention film on the bottom electrode; c) forming a dielectric thin film on the inter-electrode dielectric thin film diffusion prevention film and having a plurality of layers with different charge trap densities; and d) forming a top electrode on the dielectric thin film. The manufacturing method may further include the step of fouling an internal diffusion prevention film for preventing migration of charge traps between layers in the dielectric thin film.

The plurality of layers in the dielectric thin film may be formed of the same dielectric material or a different dielectric material.

In the step c), the dielectric thin film may be formed to have different charge trap densities between the layers in the dielectric thin film by adjusting the deposition conditions. The deposition condition may be at least one of a deposition temperature, a deposition time, a deposition rate and a deposition method. The deposition method may be one method selected from the group consisting of an Atomic Layer Deposition (ALD) method, a Plasma Enhanced Atomic Layer Deposition (PEALD) method, a Chemical Vapor Deposition (CVD) method, a Plasma Enhanced Chemical Vapor Deposition (PECVD) method, a Pulsed Laser Deposition (PLD) method, a Molecular Beam Epitaxy (MBE) method, and a sputtering method.

### ADVANTAGEOUS EFFECTS

The present invention can provide a resistance variable non-volatile memory device using a trap-controlled SCLC by being provided with a dielectric thin film having a plurality of layers with different charge trap densities.

In addition, the present invention can effectively control the charge trap distribution in a dielectric thin film by employing an inter-electrode dielectric thin film diffusion prevention film and an internal diffusion prevention film.

Further, the present invention can prevent migration of charge traps in a dielectric thin film to thus prevent the characteristic of a memory device from being deteriorated with the passage of time and an increase in the number of times of operation by having an internal diffusion prevention film.

Moreover, the memory device of the present invention has a simple structure, and thus is easily highly integrated and can enhance productivity.

### BRIEF DESCRIPTION OF THE DRAWINGS

FIG. 1 is a cross sectional view of a memory device in accordance with a first embodiment of the present invention.

FIGS. 2 to 4 are process cross-sectional views showing a manufacturing method of the memory device in accordance with the first embodiment of the present invention.

FIG. 5 is a cross-sectional view showing a memory device in accordance with a second embodiment of the present invention.

FIG. 6 is a graph showing the current-voltage hysteresis curve of the memory device in accordance with the first embodiment of the present invention.

FIG. 7 is a graph showing the current-time characteristics of the memory device in accordance with the first embodiment of the present invention.

FIG. 8 is a Scanning Electron Microscope (SEM) image showing a cross section of a titanium oxide film formed on a silicon oxide film.

FIG. 9 is an SEM image showing a cross section of a titanium oxide film formed between aluminum electrodes in accordance with the first embodiment of the present invention.

FIG. 10 is an SEM image showing an inter-electrode dielectric thin film diffusion prevention film in accordance with the first embodiment of the present invention.

FIG. 11 is an SEM image showing the distribution of oxygen atoms of the titanium oxide film formed between the aluminum electrodes in accordance with the first embodiment of the present invention.

### MODE FOR THE INVENTION

The advantages, features and aspects of the invention will become apparent from the following description of the embodiments with reference to the accompanying drawings, which is set forth hereinafter. Hereinafter, preferred embodiments of the present invention will be set forth in detail with reference to the accompanying drawings so that the invention can easily be carried out by those skilled in the art.

The memory device of the present invention is a resistance variable non-volatile memory device using a trap-controlled SCLC. For this, a dielectric thin film having a plurality of layers with different charge trap densities is included therein, and information is stored by using a phenomenon that the resistance of the dielectric thin film varies as a voltage applied to electrodes formed on the top and bottom of the dielectric thin film.

Herein, the resistance state, i.e., a high resistance state or low resistance state of the dielectric thin film, is continuously maintained even if no voltage is applied, and thus, the memory device of the present invention can be applied as a resistance variable non-volatile memory like a ReRAM.

Hereinafter, the dielectric thin film in the memory device of the present invention will be described more concretely.

In general, current hardly flows through a dielectric unlike metal and semiconductor.

However, if a dielectric thin film has a very small thickness, for example, less than 100 nm, current may flow depending on an applied voltage. In this case, an ohmic current that the current is in proportion to the voltage (I∝V²) flows when a low voltage is applied to the dielectric thin film, and an SCLC that the current is in proportion to the square of the voltage (I∝V²) flows when a high voltage is applied thereto.

This SCLC is formed by the charge traps existing in the dielectric thin film, and depending on whether charge is trapped in the charge traps existing in the dielectric thin film or not, a trap-unfilled SCLC flows if no charge is trapped in the charge traps, and a trap-filled SCLC flows if charge is trapped in the charge traps. Such an SCLC is determined by the following equation:

MathFigure 1

$$J = \frac{9}{8} ɛ μ θ \frac{{V}^{2}}{{d}^{3}} \qquad [ Math . 1 ]$$

wherein, J denotes a current density, E denotes a dielectric contant, μ denotes a charge mobility, V denotes a voltage, and d denotes a thickness of the thin film. And, θ denotes a ratio between a free charge density n and a trapped charge density nₜ which is given as Eq. (2) below:

MathFigure 2

$$θ = \frac{n}{{n}_{t}} \qquad [ Math . 2 ]$$

A threshold voltage V_{T} of the memory device including a dielectric thin film of the present invention can be defined by a trap-filled limit voltage, and is represented as:

MathFigure 3

$${V}_{T} = \frac{e {N}_{t} {d}^{2}}{2 ɛ} \qquad [ Math . 3 ]$$

where Nₜ denotes a trap density.

According to Eq. (3), in case of a resistance variable memory device using an SCLC, current flowing through the memory device and the threshold voltage can be controlled by adjusting a dielectric constant of the dielectric thin film, a trap density, a thickness of the dielectric thin film, and the like.

The charge trap existing in the dielectric thin film captures only one kind of charge of an electron and a hole, and in case such traps are distributed in an irregular way in a vertical direction, i.e., at upper and lower sides within the dielectric thin film, the current flowing in the thin film can be divided into a trap-filled SCLC and a trapunfilled SCLC depending on the direction of a voltage that is applied from the outside. Conductivities of the two current states set forth above are different from each other, and they can be switched to each other when the applied voltage is greater than the threshold voltage. This phenomenon makes it possible to manufacture a resistance variable non-volatile memory device and also to control the performance of the non-volatile memory device based on the kind of the dielectric and the trap characteristics.

Therefore, when a dielectric thin film having a plurality of layers with different charge trap densities is provided in accordance with the present invention, effective voltages (V₁, V₂, etc.) applied to the respective layers can be controlled by Eq. 4 below, and thus, the plurality of layers in the dielectric thin film can determine the intensity of an electric field applied to the respective layers depending on the thickness and dielectric constant thereof, and the non-volatile memory device having good operating characteristics can be manufactured by adjusting the intensity of an electric field.

MathFigure 4

$$Q = C \times V , V = {V}_{1} + {V}_{2} + … , \frac{1}{C} = \frac{1}{{C}_{1}} + \frac{1}{{C}_{2}} + … , \frac{C}{A} = \frac{{ɛ}_{0} {ɛ}_{1}}{{d}_{1}} = \frac{{ɛ}_{0} {ɛ}_{2}}{{d}_{2}} \qquad [ Math . 4 ]$$

wherein Q denotes the amount of charge, V denotes a voltage, C denotes a capacitance, A denotes a current, d denotes a thickness, and £ denotes a dielectric constant.

Hereinafter, dielectric materials applicable to the dielectric thin film of the present invention will be described in detail.

The dielectric materials applicable to the dielectric thin film of the present invention may be one of dielectric metal oxides comprised of a combination of one metal selected from the group consisting of titanium (Ti), vanadium (V), chrome (Cr), manganese (Mn), iron (Fe), cobalt (Co), nickel (Ni), copper (Cu), zinc (Zn), yttrium (Y), zirconium (Zr), niobium (Nb), lead (Pb), hafnium (Hf), tantalum (Ta), tungsten (W), and palladium (Pb) and oxide. For example, binary metal oxides, such as TiO₂, ZrO₂, HfO₂, V₂O₅, Nb₂O₅, Ta₂O₅, NiO, and PdO, may be used. Although the aforementioned dielectric metal oxides are high resistance materials that generally have a specific resistance of 10⁶ Ωcm or more, current may flow if they are formed to have a thickness ranging from 3 nm to 100 nm.

Alternatively, it is also possible to use a material in which one element selected from the group consisting of titanium (Ti), vanadium (V), chrome (Cr), manganese (Mn), iron (Fe), cobalt (Co), nickel (Ni), copper (Cu), zinc (Zn), zirconium (Zr), hafnium (Hf), niobium (Nb), tantalum (Ta), lead (Pb), and lanthane (La) group elements is added to the aforementioned dielectric metal oxides, as an impurity.

In addition, as the dielectric materials applicable to the dielectric thin film of the present invention, a dielectric of ABO₃ type, e.g., (Group 1 element)(Group 5 element)O₃ or (Group 2 element)(Group 4 element)O₃ may be used. In this case, the dielectrics of (Group 1 element)(Group 5 element)O₃ may include LiNbO₃, LiTaO₃, NaNbO₃, (Li,Na)(Nb,Ta)O₃, and (Li,Na,K)(Nb,Ta)O₃, and so forth, and the dielectric materials of (Group 2 element)(Group 4 element)O₃ may include CaTiO₃, SrTiO₃, BaTiO₃, PbTiO₃, Pb(Zr,Ti)O₃, (Ca,Sr,Ba,Pb)(Ti,Zr)O₃, YMnO₃, and LaMnO₃, and so forth.

Besides, the dielectric materials may be a dielectric consisting of a dielectric material, e.g., Bi₄Ta₃O₁₂ or (Sr,Ba)Nb₂O₆) having a perovskite structure except the ABO₃ type mentioned above, and a specific impurity added to the material.

The dielectric material of ABO₃ type is a ferroelectric having a relatively high dielectric constant compared to other dielectric materials and has a dielectric constant of about 100 to about 1000, and the rest of the dielectrics have a dielectric constant of 3 to several hundreds. Therefore, a dielectric constant of the dielectric materials applicable to the present invention is preferably selected in a range of 3 to 1,000

Hereinafter, a most preferred embodiment of the present invention will be described with reference to the accompanying drawings. In the drawings, the thickness of layers and regions may be exaggerated for clarity. It will also be understood that when a layer or structure is referred to as being on another layer or substrate, it can be directly on the other layer or substrate or a third layer may be interposed therebetween. The same reference numerals are denoted for the same elements throughout the specification.

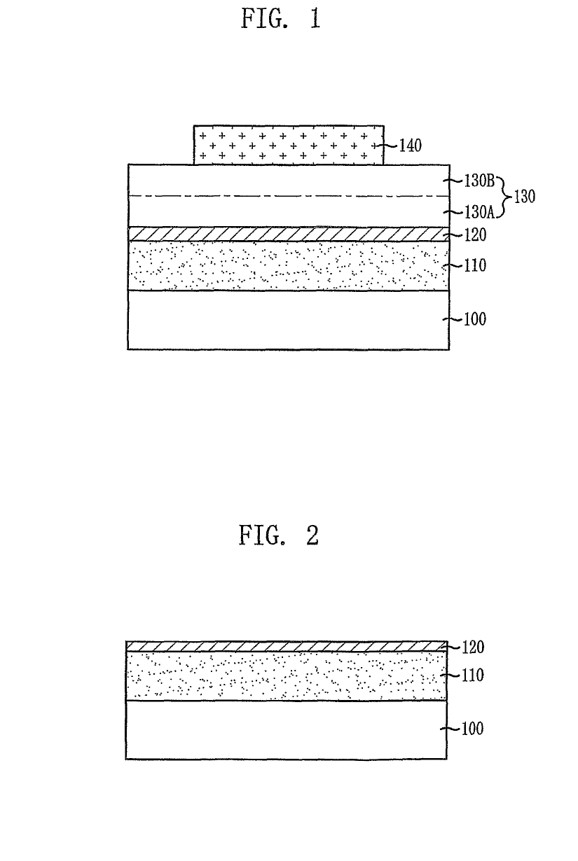

FIG. 1 is a cross-sectional view of a memory device in accordance with a first embodiment of the present invention.

As shown in FIG. 1, the memory device in accordance with the first embodiment of the present invention includes a substrate 100, a bottom electrode 110 formed on the substrate 100, an inter-electrode dielectric thin film diffusion prevention film 120 formed on the bottom electrode 110, a dielectric thin film 130 formed on the interelectrode dielectric thin film diffusion prevention film 120 and having a structure having a plurality of layers 130A and 130B with different charge trap densities, and a top electrode 140 formed on the dielectric thin film 130. The plurality of layers 130A and 130B in the dielectric thin film 130 may be formed of the same dielectric material or a different dielectric material. In the first embodiment of the present invention, the same dielectric material is used.

The dielectric thin film 130 is formed to have a relatively thin thickness so as to form a relatively large electric field with respect to a voltage applied to the memory device, and the dielectric thin film 130 is preferably formed to have a thickness of about 3 nm to 100 nm. The dielectric thin film 130 or the dielectric materials constituting the dielectric thin film have been described in detail above, so further description thereof will be omitted.

The inter-electrode dielectric thin film diffusion prevention film 120 may be formed of an oxide or nitride, for example, one selected from the group consisting of Al₂O₃, SiO₂, ZnO₂, AlN and Si₃N₄ to have a thickness of 05 nm to 3 nm or may be formed of an organic self-assembled monolayer.

The top electrode 140 and the bottom electrode 110 may be formed of one metal element selected from the group consisting of aluminum (Al), titanium (Ti), copper (Cu), zinc (Zn), silver (Ag), platinum (Pt), and gold (Au), or one conductive oxide selected from the group consisting of ITO, IZO, RuO₂, and IrO₂.

In order to implement a resistance variable non-volatile memory device using the dielectric thin film 130, the distribution of charge traps in the dielectric thin film 130 has to be uniform. For example, if electrodes are formed on the top and bottom of the dielectric thin film 130, the dielectric thin film 130 should have a uniform distribution of charge traps in a vertical direction so that an SCLC, which is an electrical transport characteristic, can flow, thereby exhibiting the characteristics of non-volatile memory devices.

Thus, the memory device in accordance with the first embodiment of the present invention is able to control the distribution of charge traps in the dielectric thin film 130 through the inter-electrode dielectric thin film diffusion prevention film 120 formed on the top of the bottom electrode 110. This will be described in more detail with reference to FIGS. 2 to 4 showing a manufacturing method of the memory device in accordance with the first embodiment of the present invention.

FIGS. 2 to 4 are process cross-sectional views showing a manufacturing method of the memory device in accordance with the first embodiment of the present invention.

As shown in FIG. 2, an aluminum film, as the bottom electrode 110, is formed on the substrate 100. The bottom electrode 110 may be formed of one metal element selected from the group consisting of titanium (Ti), copper (Cu), zinc (Zn), silver (Ag), platinum (Pt), and gold (Au), or one conductive oxide selected from the group consisting of ITO, IZO, RuO₂, and IrO₂, in stead of the aluminum film.

Next, an aluminum oxide film Al₂O₃, as the inter-electrode dielectric thin film diffusion prevention film 120, is formed on the bottom electrode 110 so as to have a thickness of 05 nm to 3 nm. The aluminum oxide film may be formed by exposing the aluminum bottom electrode 110 to oxygen O₂ in the air or by supplying an oxygen gas in a vacuum chamber and oxidizing the surface of the aluminum bottom electrode 110

Meanwhile, the inter-electrode dielectric thin film diffusion prevention film 120 may be formed of an oxide or nitride, for example, one selected from the group consisting of SiO₂, ZnO₂, AlN, and Si₃N₄, or an organic self-assembled monolayer, in place of an aluminum oxide film.

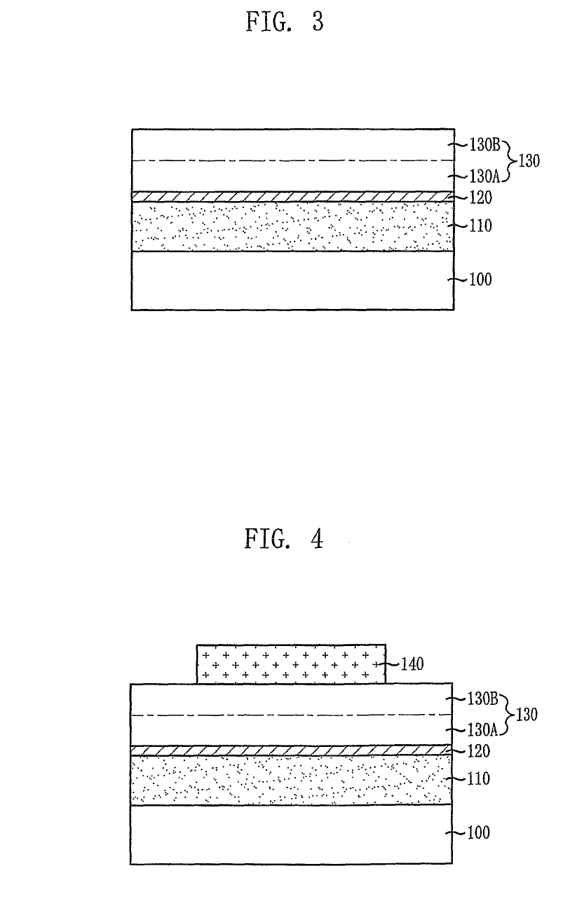

As shown in FIG. 3, a titanium oxide film TiO₂, as the dielectric thin film 150, is formed on the inter-electrode dielectric thin film diffusion prevention film 120. At this time, the dielectric thin film 130 may be formed by one method selected from the group consisting of an Atomic Layer Deposition (ALD) method, a Plasma Enhanced Atomic Layer Deposition (PEALD) method, a Chemical Vapor Deposition (CVD) method, a Plasma Enhanced Chemical Vapor Deposition (PECVD) method, a Pulsed Laser Deposition (PLD) method, an Molecular Beam Epitaxy (MBE) method, and a sputtering method.

Here, charge traps can be formed in the titanium oxide film by adjusting the amount of oxygen elements existing in the titanium oxide film in the process of fouling a titanium oxide film. The principle of producing charge traps in the titanium oxide film is as follows.

If a material with no oxygen loss in a titanium oxide film is assumed to be TiO₂, a material with oxygen loss therein may be expressed as TiO₂—X. The titanium oxide film is comprised of a chemical bond of Ti⁺⁴ and 2_{O-2}. In case of TiO_{2-X}, crystalline defects such as oxygen vacancies occur in the titanium oxide film because of oxygen deficiency, or a material having a different composition ratio of Ti and O and Ti⁺³, which is positive trivalent, rather than positive tetravalent, is produced, to thus produce charge traps.

In other words, it is possible to form charge traps in the titanium oxide film by adjusting the deposition conditions so that oxygen to be bound to titanium is excessive or deficient. Preferably, the variation range of oxygen is −0.2<X<0.6 so that oxygen to be bound to titanium is excessive or deficient.

Based on the above-described principle, charge traps can be formed in the dielectric thin film 130, and therefore, if such charge traps are nonuniformly distributed in the dielectric thin film 130, an SCLC, which is an electric transport characteristic, may flow, thereby exhibiting the characteristics of non-volatile memory devices.

As shown in FIG. 4, an aluminum film, as the top electrode 140, is formed on the dielectric thin film 130. The top electrode 140 may be formed of one metal element selected from the group consisting of titanium (Ti), copper (Cu), zinc (Zn), silver (Ag), platinum (Pt), and gild (Au), or one conductive oxide selected from the group consisting of ITO, IZO, RuO₂, and IrO₂, in place of an aluminum film.

Here, it is possible to control the distribution of charge traps in the dielectric thin film 130 while fouling the top electrode 140. This will be described in detail below.

When the material used as the electrodes and the dielectric thin film 130 are bonded, a mutual diffusion between materials occurs on the interface between the electrode and the dielectric thin film 130 depending on the degree of oxidation of each element, and thus, an interface layer having a thickness of several nm may be formed. In other words, as a top interface layer and a bottom interface layer are formed on the top and bottom of the dielectric thin film 130, respectively, by the oxygen being diffused from the titanium oxide film, which is the dielectric thin film 130, to the direction of the aluminum electrode, an oxygen loss occurs in the titanium oxide film. At this time, the distribution of oxygen content in the titanium oxide film, i.e., the distribution of charge traps, is arbitrarily controlled by preventing the diffusion of oxygen or facilitating the diffusion of oxygen, thereby forming the dielectric thin film 130 having the plurality of layers 130A and 130B with different charge trap densities.

In summary, when the top aluminum film with no inter-electrode dielectric thin film diffusion prevention film 120 formed thereon and the titanium oxide film 150 are bonded, a mutual diffusion of elements occurs at the junctions depending on the degree of oxidation of titanium and aluminum, thereby forming a top interface layer comprised of aluminum-titanium oxide. Accordingly, as an oxygen loss occurs at the upper region in the titanium oxide film, the upper region in the titanium oxide film forms the layer 130B with a high charge trap density.

Meanwhile, when the bottom aluminum film with the inter-electrode dielectric thin film diffusion prevention film 120 formed thereon and the titanium oxide film are bonded, the inter-electrode dielectric thin film diffusion prevention film 120 prevents oxygen deficiency at the lower region in the titanium oxide film, and thus, the lower region in the titanium oxide film forms the layer 130A with a low charge trap density.

As described above, the memory device in accordance with the first embodiment of the present invention can form a dielectric thin film 130 having a plurality of layers 130A and 130B with different charge trap densities by fouling an inter-electrode dielectric thin film diffusion prevention film 120. By this, it is possible to form a resistance variable non-volatile memory device using a trap-controlled SCLC.

Further, the memory device has a simple structure where the top electrode 140, the dielectric thin film 130, and the bottom electrode 110 are stacked, thereby making high integration easier and in turn enhancing the productivity of the memory device.

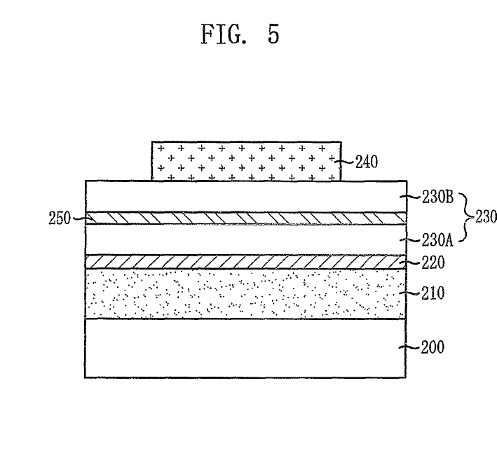

FIG. 5 is a cross-sectional view showing a memory device in accordance with a second embodiment of the present invention.

As shown in FIG. 5, the memory device in accordance with the second embodiment of the present invention includes a substrate 200, a bottom electrode 210 formed on the substrate 200, an inter-electrode dielectric thin film diffusion prevention film 220 formed on the bottom electrode 210, a dielectric thin film 230 formed on the interelectrode dielectric thin film diffusion prevention film 220 and having a structure having a plurality of layers 230A and 230B with different charge trap densities, an internal diffusion prevention film 250 for preventing migration of charge traps between the layers in the dielectric thin film, and a top electrode 240 formed on the dielectric thin film 230. The plurality of layers 230A and 230B in the dielectric thin film 230 may be formed of the same dielectric material or a different dielectric material.

The dielectric thin film 130 is formed to have a relatively thin thickness so as to form a relatively large electric field with respect to a voltage applied to the memory device, and the dielectric thin film 130 is preferably formed to have a thickness of 3 nm to 100 nm. The dielectric thin film 130 or the dielectric materials constituting the dielectric thin film have been described in detail above, so further description thereof will be omitted.

Additionally, when the respective layers in the dielectric thin film 230 having the plurality of dielectric layers 230A and 230B having different trap charge densities is formed by using the same dielectric material, the plurality of layers 230A and 230B having different charge trap densities can be formed by making deposition conditions, e.g., deposition temperature, deposition time, deposition rate, deposition method, or the like, different from each other for each layer in consideration of intrinsic defects generated due to lack or excess of specific atoms among atoms constituting a dielectric material or extrinsic defects generated due to doped impurities.

Moreover, when the respective layers are formed by using different dielectric materials, the same deposition condition and different deposition conditions can be used, and the plurality of layers 230A and 230B with different charge trap densities can be formed even when the same deposition condition is used.

The inter-electrode dielectric thin film diffusion prevention film 220 and the internal diffusion prevention film 250 may be formed of an oxide or nitride, for example, one selected from the group consisting of Al₂O₃, SiO₂, ZnO₂, AlN, and Si₃N₄, so as to have a thickness ranging from 05 nm to 3 nm, or of an organic self-assembled monolayer.

The top electrode 240 and the bottom electrode 210 may be formed of one metal element selected from the group consisting of aluminum (Al), titanium (Ti), copper (Cu), zinc (Zn), silver (Ag), platinum (Pt), and gold (Au), or one conductive oxide selected from the group consisting of ITO, IZO, RuO₂, and IrO₂.

As described above, the memory device in accordance with the second embodiment of the present invention can form a resistance variable non-volatile memory device using a trap-controlled SCLC by being provided with a dielectric thin film 230 having a plurality of layers 230A and 230B with different charge trap densities.

In addition, the memory device can effectively control the charge trap distribution in a dielectric thin film 230 by having an inter-electrode dielectric thin film diffusion prevention film 220 and an internal diffusion prevention film 250

Further, the memory device can prevent migration of charge traps in a dielectric thin film 230, to thus prevent the characteristic of a memory device from being deteriorated with the passage of time and an increase in the number of times of operation by including an internal diffusion prevention film 250

Moreover, the memory device has a simple structure where the top electrode 240, the dielectric thin film 230, and the bottom electrode 210 are stacked, thereby making high integration easier and in turn enhancing the productivity of the memory device.

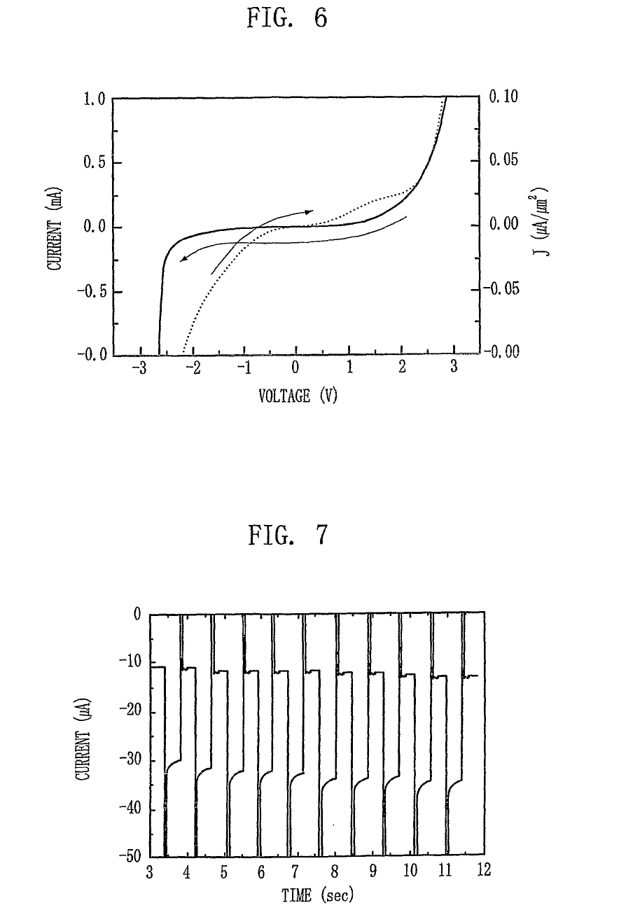

FIG. 6 is a graph showing the current-voltage hysteresis curve of the memory device in accordance with the first embodiment of the present invention.

Referring to FIG. 6, the current-voltage curve indicated by a black solid line shows a change in current when the voltage is changed from a positive to a negative voltage direction, and a red dotted line shows a change in current when the voltage is changed from a negative to a positive voltage direction.

The black solid line shows a high resistance state where a smaller current flows as compared to the red dotted line, and changes to a red dotted line state when the magnitude of the voltage is around −2.6 V. The red dotted line shows a low resistance state where a larger current flows throughout the entire area as compared to the black solid line, and changes to a high resistance state, i.e., the black solid line state, when the voltage is gradually increased to around +2 V. It can be seen that such a state change is shown repetitively and stably depending on a change in voltage.

Based on this, the operation of the memory device in accordance with the first embodiment of the present invention shows a state change at a voltage less than −2.6 V and greater than +2 V. Thus, this period of time can be defined as write and erase operations or erase and write operations, respectively.

A read operation is enabled at a voltage greater than −2.5 V and less than 0 V, preferably, at a voltage greater than −1 V and less than 01 V. Moreover, when the operational characteristics of the memory device are measured, there are limits to the magnitude of operating current for the safety of the device, which fall within the range from 1 uA/μm² to 0.01 uA/μm², preferably, 0.1 uA/μm².

FIG. 7 is a graph showing the current-time characteristics of the memory device in accordance with the first embodiment of the present invention.

Referring to FIG. 7, −3 V, −1 V, +3 V, and −1 V are repetitively applied to measure a change in current with time. It can be seen that the magnitude of negative current at a voltage from −3 V to −1 V is larger than the magnitude of negative current at a voltage from +3 V to −1 V.

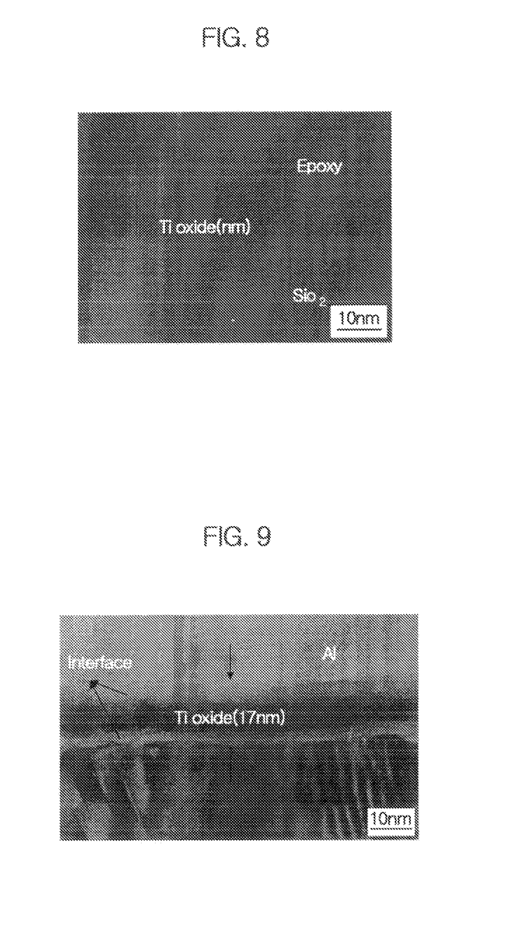

FIG. 8 is a Scanning Electron Microscope (SEM) image showing a cross section of a titanium oxide film formed on a silicon oxide film. FIG. 9 is a SEM image showing a cross section of a titanium oxide film formed between aluminum electrodes in accordance with the first embodiment of the present invention.

In comparison of FIG. 8 with FIG. 9, it can be seen that the thickness of a titanium oxide thin film formed under the same conditions is increased from 9 nm in FIG. 8 to 17 nm in FIG. 9. This is the result of a mutual diffusion of elements between the titanium oxide thin film and the aluminum electrodes (see FIGS. 2 and 3).

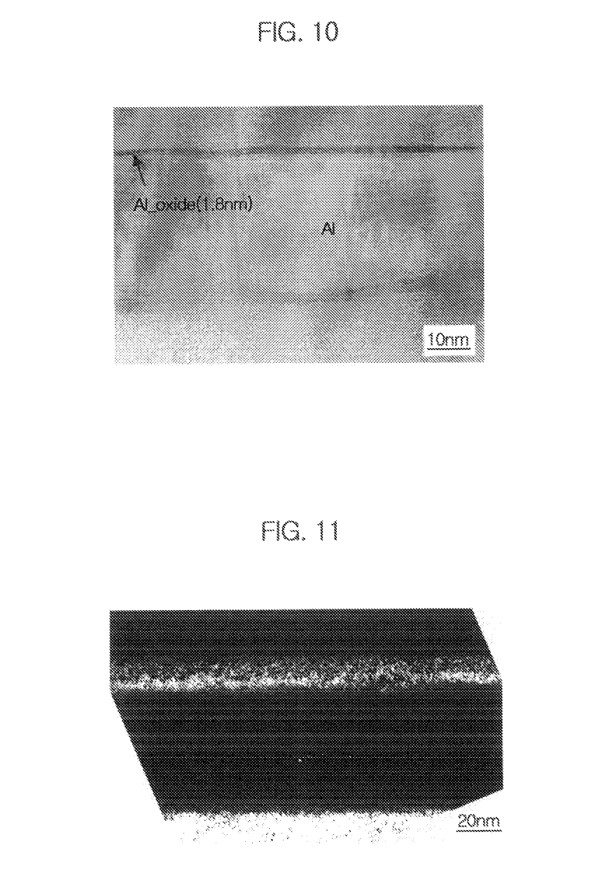

FIG. 10 is an SEM image showing the inter-electrode dielectric thin film diffusion prevention film in accordance with the first embodiment of the present invention.

Referring to FIG. 10, it can be seen that an aluminum oxide film, as the interelectrode dielectric thin film diffusion prevention film, is formed on the aluminum electrodes at a thickness of about 1.8 nm.

FIG. 11 is an SEM image showing the distribution of oxygen atoms of the titanium oxide film formed between the aluminum electrodes in accordance with the first embodiment of the present invention.

Referring to FIG. 11, it can be seen that, in the titanium oxide film, the lower region has a deep color and the upper region has a light color. At this time, the lower region having a deep color represents an area in which a large amount of oxygen atoms are distributed, i.e., the charge trap density is low, because no oxygen deficiency occurs due to the inter-electrode dielectric thin film diffusion prevention film formed on the bottom electrode.

In contrast, the upper region having a light color represents a region area in which a small amount of oxygen atoms are distributed, i.e., the charge trap density is high, because an oxygen deficiency occurs in the process of forming a dielectric thin film. In this way, the inter-electrode dielectric thin film diffusion prevention film is formed to control mutual diffusion of oxygen atoms between the dielectric thin film and the electrodes, thereby controlling the distribution of charge traps in the dielectric thin film (see FIGS. 2 to 4 and FIG. 9).

As described above, the memory device of the present invention can implement a resistance variable non-volatile memory device using a trap-controlled SCLC by including an inter-electrode dielectric thin film diffusion prevention film.

Also, the memory device has a simple structure where the top electrode, the dielectric thin film, and the bottom electrode are stacked, thereby making high integration easier and in turn enhancing the productivity of the memory device.

The present application contains subject matter related to Korean Patent Application Nos. 2006-0121755 and 2007-0084717, filed in the Korean Intellectual Property Office on Dec. 4, 2006; and Aug. 23, 2007, the entire contents of which are incorporated herein by reference.

While the present invention has been described with respect to the particular embodiments, it will be apparent to those skilled in the art that various changes and modifications may be made without departing from the spirit and scope of the invention as defined in the following claims.

1. A memory device, comprising:
a bottom electrode;
an inter-electrode dielectric thin film diffusion prevention film formed on the bottom electrode;
a dielectric thin film formed on the inter-electrode dielectric thin film diffusion prevention film and having a plurality of layers with different charge trap densities; and
a top electrode formed on the dielectric thin film.

2. The memory device of claim 1, further comprising an internal diffusion prevention film for preventing migration of charge traps between layers in the dielectric thin film.

3. The memory device of claim 1, wherein the plurality of layers in the dielectric thin film are formed of the same dielectric material or a different dielectric material.

4. The memory device of claim 1, wherein a different Space Charge Limit Current (SCLC) flows in the dielectric thin film depending on the charge trap densities.

5. The memory device of claim 1, wherein the dielectric thin film is formed of one of dielectric metal oxides comprised of a combination of one metal selected from the group consisting of titanium (Ti), vanadium (V), chrome (Cr), manganese (Mn), iron (Fe), cobalt (Co), nickel (Ni), copper (Cu), zinc (Zn), yttrium (Y), zirconium (Zr), niobium (Nb), lead (Pb), hafnium (Hf), tantalum (Ta), tungsten (W), and palladium (Pb) and oxide.

6. The memory device of claim 5, wherein the dielectric thin film is formed of a material in which one element selected from the group consisting of titanium (Ti), vanadium (V), chrome (Cr), manganese (Mn), iron (Fe), cobalt (Co), nickel (Ni), copper (Cu), zinc (Zn), zirconium (Zr), hafnium (Hf), niobium (Nb), tantalum (Ta), lead (Pb), and lanthane (La) group elements is added to the aforementioned dielectric metal oxides, as an impurity.

7. The memory device of claim 1, wherein the inter-electrode dielectric thin film diffusion prevention film and the internal diffusion prevention film are formed of an oxide or nitride.

8. The memory device of claim 1, wherein the inter-electrode dielectric thin film diffusion prevention film and the internal diffusion prevention film are formed of an organic self-assembled monolayer.

9. The memory device of claim 1, wherein the inter-electrode dielectric thin film diffusion prevention film and the internal diffusion prevention film are formed to have a thickness of 05 nm to 3 nm.

10. The memory device of claim 1, wherein the inter-electrode dielectric thin film diffusion prevention film is formed of one selected from the group consisting of Al₂O₃, SiO₂, ZnO₂, AlN and Si₃N₄.

11. The memory device of claim 1, wherein the dielectric thin film is formed to have a thickness of 3 nm to 100 nm.

12. The memory device of claim 1, wherein the materials forming the dielectric thin film have a dielectric constant of 3 to 1,000.

13. The memory device of claim 1, wherein the top electrode and the bottom electrode are formed of one metal element selected from the group consisting of aluminum (Al), titanium (Ti), copper (Cu), zinc (Zn), silver (Ag), platinum (Pt), and gold (Au).

14. The memory device of claim 1, wherein the top electrode and the bottom electrode are formed of one conductive oxide selected from the group consisting of ITO, IZO, RuO₂, and IrO₂.

15. A manufacturing method of a memory device, comprising the steps of:
a) forming a bottom electrode;
b) forming an inter-electrode dielectric thin film diffusion prevention film on the bottom electrode;
c) forming a dielectric thin film on the inter-electrode dielectric thin film diffusion prevention film and having a plurality of layers with different charge trap densities; and
d) forming a top electrode on the dielectric thin film.

16. The manufacturing method of claim 15, further comprising the step of forming an internal diffusion prevention film for preventing migration of charge traps between layers in the dielectric thin film.

17. The manufacturing method of claim 15, wherein the plurality of layers in the dielectric thin film are formed of the same dielectric material or a different dielectric material.

18. The manufacturing method of claim 15, wherein in the step c) the dielectric thin film is formed to have different charge trap densities between the layers in the dielectric thin film by adjusting the deposition conditions.

19. The manufacturing method of claim 18, wherein the deposition condition is at least one of a deposition temperature, a deposition time, a deposition rate and a deposition method.

20. The manufacturing method of claim 19, wherein the deposition method is one method selected from the group consisting of an Atomic Layer Deposition (ALD) method, a Plasma Enhanced Atomic Layer Deposition (PEALD) method, a Chemical Vapor Deposition (CVD) method, a Plasma Enhanced Chemical Vapor Deposition (PECVD) method, a Pulsed Laser Deposition (PLD) method, a Molecular Beam Epitaxy (MBE) method, and a sputtering method.
